(19) United States
(12) Patent Application Publication
(10) Pub. No.: US 2013/0265097 A1
(43) Pub. Date: Oct. 10, 2013

(54) SEMICONDUCTOR INTEGRATED CIRCUIT

(71) Applicant: KABUSHIKI KAISHA TOSHIBA, Tokyo (JP)

(72) Inventors: Masafumi MIYAZAWA, Tokyo (JP); Masaki NODA, Shizuoka-ken (JP)

(73) Assignee: KABUSHIKI KAISHA TOSHIBA, Tokyo (JP)

(21) Appl. No.: 13/776,323

(22) Filed: Feb. 25, 2013

(30) Foreign Application Priority Data
Apr. 6, 2012 (JP) 2012-087606

(51) Int. Cl. H03K 17/687

(52) U.S. Cl. CPC H03K 17/687
USPC 327/434

(57) ABSTRACT

An aspect of the present embodiment, there is provided a semiconductor integrated circuit, including a first transistor configured to switch whether or not a first node electrically connects to a second node, and a switch control circuit configured to supply higher potential to a substrate potential of the first transistor in a state of turning of the first transistor, when at least one of potentials of the first node and the second node is equal to or higher than a predetermined potential which is higher than a potential of a power supply.

### CROSS REFERENCE TO RELATED APPLICATION

This application is based upon and claims the benefit of priority from prior Japanese Patent Application No. 2012-087606, filed on Apr. 6, 2012, the entire contents of which are incorporated herein by reference.

### FIELD

Embodiments described herein relate generally to a semiconductor integrated circuit to electrically connect or disconnect two nodes to or from each other by turning on and off a transistor in the circuit.

### BACKGROUND

An analog switch is used to turn on or off P-channel MOS and N-channel MOS transistors in synchronization with logic of a switch control signal. The P-channel MOS and N-channel MOS transistors are connected in parallel with each other between two nodes.

A circuit disclosed turns off both the P-channel MOS and N-channel MOS transistors reliably independently of electric potential between the two nodes when turning off the analog switch.

The circuit feeds back a substrate potential of the P-channel MOS transistor in the analog switch to a gate of the P-channel MOS transistor when turning off the analog switch. Accordingly, the circuit supplies almost the same potential as the potential at a terminal of the analog switch to the gate so as to turn off the analog switch stably.

The P-channel MOS transistor parasitizes a parasitic diode between the source and drain of the P-channel MOS transistor. Therefore, a potential lower by forward potential of the parasitic diode is given to the gate of the P-channel MOS transistor from the terminal.

As a result, the P-channel MOS transistor is sometimes in a weak ON state because the P-channel MOS transistor cannot be completely turned OFF. Then, the weak ON state increases a leak current when the analog switch is turned off.

### BRIEF DESCRIPTION OF THE DRAWINGS

FIG. 1 is a circuit diagram of a semiconductor integrated circuit 1 according to a first embodiment.

FIG. 2 is a circuit diagram of a semiconductor integrated circuit 1 according to a comparative example.

FIG. 3 is a circuit diagram showing a current pass without supplying power-supply potential.

FIG. 4 is a circuit diagram showing a current pass with supplying power-supply potential.

FIG. 5 is a graph showing characteristics of an analog switch being turned off in FIGS. 1 and 2 when the analog switch is supplied the power-supply potential.

FIG. 6 is a graph showing characteristics of an analog switch being turned off in FIGS. 1 and 2 when the analog switch is not supplied the power-supply potential.

FIG. 7 is a circuit diagram where a diode in an inverter is formed of a P-channel MOS transistor.

FIG. 8 is a circuit diagram of a semiconductor integrated circuit according to a second embodiment.

FIG. 9 is a circuit diagram of a semiconductor integrated circuit according to a third embodiment.

FIG. 10 is a circuit diagram of a semiconductor integrated circuit to which a substrate bias circuit of FIG. 8 and a potential-speed-up circuit of FIG. 9 are added.

FIG. 11 is a circuit diagram of a semiconductor integrated circuit according to a fourth embodiment.

### DETAILED DESCRIPTION

An aspect of the present embodiment, there is provided a semiconductor integrated circuit, including a first transistor configured to switch whether or not a first node electrically connects to a second node, and a switch control circuit configured to supply higher potential to a substrate potential of the first transistor in a state of turning of the first transistor, when at least one of potentials of the first node and the second node is equal to or higher than a predetermined potential which is higher than a potential of a power supply.

Embodiments will be described with reference to the drawings. The accompanying drawings, which are incorporated in and constitute a part of this specification, illustrate embodiments and together with the description, serve to explain the principles of the invention.

### First Embodiment

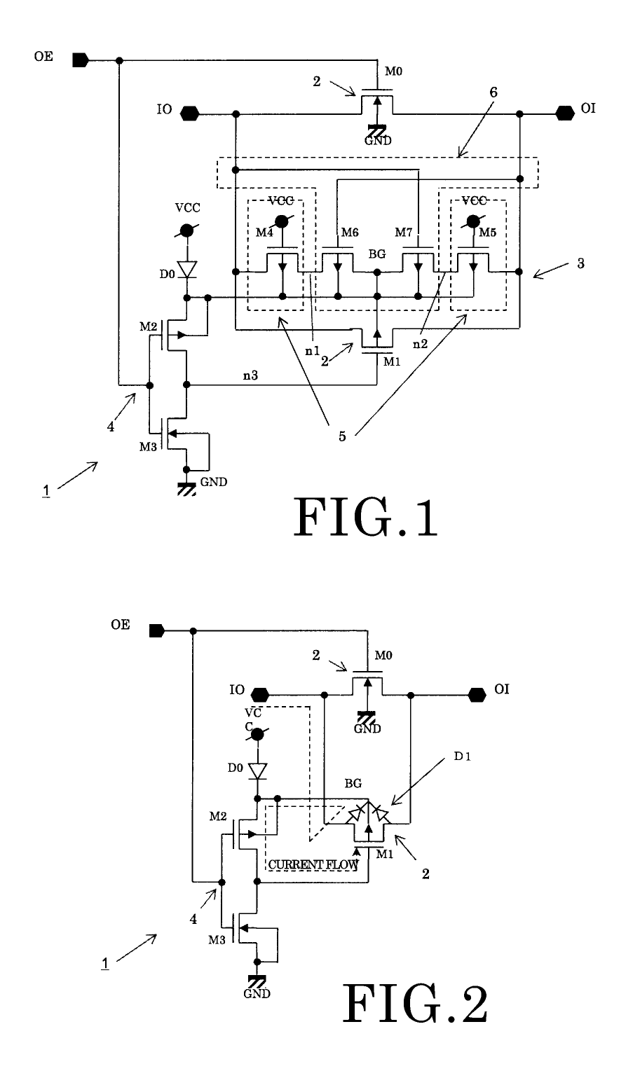

FIG. 1 is a circuit diagram of a semiconductor integrated circuit 1 according to a first embodiment. The semiconductor integrated circuit 1 includes an analog switch 2 configured to have a P-channel MOS transistor (hereinafter referred to as a “PMOS transistor”) and an N-channel MOS transistor (hereinafter referred to as a “NMOS transistor”). Both the PMOS and NMOS transistors are formed on a semiconductor substrate by a CMOS process. The semiconductor integrated circuit 1 according to the first embodiment includes a high-voltage analog switch 2 with a tolerant function on the semiconductor substrate.

The semiconductor integrated circuit 1 of FIG. 1 includes the analog switch 2, a switch control circuit 3, and an inverter 4. The analog switch 2 is configured to electrically connect or disconnect a first node IO to a second node OI. The switch control circuit 3 is configured to control turning on or off the analog switch 2. The inverter 4 is configured to invert a switch control signal OE to supply the signal to the switch control circuit 3.

The analog switch 2 has a NMOS transistor M0 and a PMOS transistor (first transistor) M1, both being connected in parallel with each other between the first node IO and the second node OI.

The NMOS transistor M0 and the PMOS transistor M1 are turned on or off corresponding to logic of the switch control signal OE inputted from outside. The switch control signal OE is inputted into the gate of the NMOS transistor M0 corresponding to logic of the switch control signal. The switch control signal OE inverted by the inverter 4 is inputted into the gate of the PMOS transistor M1. As a result, the NMOS transistor M0 and the PMOS transistor M1 are turned on or off in synchronization.

A substrate potential of the NMOS transistor M0 is set to ground potential GND, and a substrate potential of the PMOS transistor M1 is connected to an output node BG of the switch control circuit 3.

The inverter 4 includes a diode D0, a PMOS transistor M2, and an NMOS transistor M3. The diode D0 is electrically vertically laminated between power-supply potential VCC and the ground potential GND. An anode of the diode D0 is set to the power-supply potential VCC, and a cathode thereof is connected to the output node BG of the switch control circuit 3. A source of the PMOS transistor M2 is connected to the output node BG of the switch control circuit 3, and a drain thereof is connected to an output node n3 of the inverter 4. A drain of the NMOS transistor M3 is connected to the output node n3 of the inverter 4, and a source thereof is grounded.

The switch control circuit 3 supplies the higher potential to a substrate potential and a gate potential of the PMOS transistor M1 in cases described below. First, the PMOS transistor M1 in the analog switch 2 is turned off to electrically disconnect the first node IO to the second node OI. Next, at least one of potentials of the first node IO and the second node OI has higher potential than a predetermined voltage (threshold voltage) which is higher than a power supply with potential VCC. In addition, the substrate potential of the PMOS transistor M1 is equivalent to a back gate potential of the PMOS transistor M1.

The switch control circuit 3 includes a power-supply-potential detection circuit 5 and a potential comparison circuit 6.

The power-supply-potential detection circuit 5 determines whether or not at least one of the potentials of the first node IO and the second node OI is higher than the power-supply potential VCC. More specifically, the power-supply-potential detection circuit 5 supplies potential of the first node IO from a third node n1 when potential of the first node IO is higher than the power-supply-potential VCC. Further, the power-supply-potential detection circuit 5 supplies the potential of the second node OI from a fourth node n2 when the potential of the second node OI is higher than the power-supply-potential VCC.

The potential comparison circuit 6 selects higher potential from the potentials of the first and second nodes IO and OI to supply the higher potential to the substrate potential of the first transistor when the power-supply-potential detection circuit 5 determines that at least one of the first node IO and the second node OI has potential higher than the power-supply potential VCC.

The power-supply-potential detection circuit 5 includes a PMOS transistor M4 and a PMOS transistor M5. The PMOS transistor M4 is connected to a line between the first node IO and the first input node n1 of the potential comparison circuit 6. The PMOS transistor M5 is connected to a line between the second node OI and the second input node n2 of the potential comparison circuit 6. The source of the PMOS transistor M4 is connected to the first node IO, the drain of the PMOS transistor M4 is connected to the first input node n1 of the potential comparison circuit 6, and the power-supply potential VCC is supplied to the gate thereof. The source of the PMOS transistor M5 is connected to the second node OI, the drain of the PMOS transistor M5 is connected to the second input node n2 of the potential comparison circuit 6, and the power-supply potential VCC is supplied to the gate of the PMOS transistor M5.

The PMOS transistor M4 is turned on to supply a potential of the first node IO to the potential comparison circuit 6 when the potential of the first node IO is higher than the total of the power-supply potential VCC and the threshold potential of the PMOS transistor M4. The PMOS transistor M5 is turned on to supply a potential of the second node OI to the potential comparison circuit 6 when the potential of the second node OI is higher than the total of the power-supply potential VCC and the threshold potential of the PMOS transistor M5.

The potential comparison circuit 6 includes PMOS transistors M6 and M7. A source of the PMOS transistor M6 is connected to the drain of the PMOS transistor M4, a drain of the PMOS transistor M6 is connected to an output node BG of the potential comparison circuit 6, and a gate of the potential comparison circuit 6 is connected to the second node OI. A source of the PMOS transistor M7 is connected to the drain of the PMOS transistor M5, a drain of the PMOS transistor M7 is connected to the output node BG of the potential comparison circuit 6, and the gate of the PMOS transistor M7 is connected to the first node IO.

The PMOS transistor M6 is turned on when the drain of the PMOS transistor M4 has potential higher than the total of potential of the second node OI and the threshold potential of the PMOS transistor M6. As a result, the drain of the PMOS transistor M6 has almost the same potential as the drain of the PMOS transistor M4. The PMOS transistor M6 is turned on when the PMOS transistor M4 is turned on. The drain of the PMOS transistor M6 has the same potential as the first node IO when the PMOS transistor M6 is turned on.

The PMOS transistor M7 is turned on when the drain of the PMOS transistor M5 has a potential higher than the total of potentials of the first node IO and the threshold potential of the PMOS transistor M7. As a result, the drain of the PMOS transistor M7 has almost the same potential as the drain of the PMOS transistor M5. The PMOS transistor M7 is turned on when the PMOS transistor M5 is turned on. The drain of the PMOS transistor M7 has the same potential as the second node OI when the PMOS transistor M7 is turned on.

Thus, a drain potential of the PMOS transistor M6 is supplied to the potential of the first node IO when the PMOS transistor M4 is turned on in the power-supply-potential detection circuit. In the same way, a drain potential of the PMOS transistor M7 is supplied the potential of the second node OI when the PMOS transistor M5 is turned on in the power-supply-potential detection circuit 5.

Both the drains of the PMOS transistor M6 and the PMOS transistor M7 are connected to the output node BG of the potential comparison circuit 6. As a result, the potential of the output node BG is supplied higher potential from potentials of the PMOS transistor M6 and the PMOS transistor M7.

Thus, the power-supply-potential detection circuit 5 determines whether or not the first node IO has higher potential than the potential VCC of the power supply, and whether or not the second node OI has higher potential than the potential VCC of the power supply. When at least one of the first node IO and the second node OI has higher potential than the potential VCC of the power supply, the potential comparison circuit 6 outputs the higher potential.

The PMOS transistor M4 is turned off when the potential of the first node IO is lower than the total of the power-supply potential VCC and the threshold potential of the PMOS transistor M4. The PMOS transistor M5 is turned off when the potential of the second node OI is lower than the total of the power-supply potential VCC and the threshold potential of the PMOS transistor M5. When the PMOS transistor M4 is turned off, the PMOS transistor M6 is also turned off. When the PMOS transistor M5 is turned off, the PMOS transistor M7 is also turned off.

When both the PMOS transistor M6 and the PMOS transistor M7 are turned off, the output node BG of the potential comparison circuit 6 is in a high-impedance state. When either one of the two PMOS transistors M6 and M7 is turned on, the output node BG of the potential comparison circuit 6 has the same potential as the source of the one transistor that has been turned on. The source of the transistor turned on has the same potential as the first node IO or the second node OI.

Operation of the semiconductor integrated circuit 1 of FIG. 1 will be described below. When the switch control signal OE is high, both the NMOS transistor M0 and the PMOS transistor M1 are turned on so that the first node IO is electrically connected to the second node OI. The analog switch 2 has been turned on in this state.

When the switch control signal OE is low, both the NMOS transistor M0 and the PMOS transistor M1 are turned off so that the first node IO are electrically disconnected from the second node OI. The analog switch 2 has been turned off in this state.

When the analog switch 2 is turned off, at least one of the first node IO and the second node OI is assumed to have higher potential than the power supply with the potential VCC. For example, when the potential of the first node IO becomes not lower than the total of the power-supply potential VCC and the threshold potential of the PMOS transistor M4, the PMOS transistor M4 is turned on so that the source of the PMOS transistor M6 is supplied to the potential of the first node IO. Since the potential of the second node OI has been supplied to the gate of the PMOS transistor M6, the PMOS transistor M6 is turned on when the potential of the first node IO is not lower than the total of the potential of the second node OI and the threshold potential of the PMOS transistor M6.

When the potential of the first node is not lower than the total of the potential of the second node OI and the threshold potential of the PMOS transistor M5 in a state of turning off the analog switch 2, the PMOS transistor M5 is turned on so that the source potential of the PMOS transistor M7 is supplied to the potential of the second node OI. The potential of the first node IO has been supplied to the gate of the PMOS transistor M7. Accordingly, the PMOS transistor M7 is turned on when the potential of the second node OI is not lower than the total of the potential of the first node IO and the threshold potential of the PMOS transistor M7.

Thus, at least one of potentials of the first node IO and the second node OI is supplied to the potential comparison circuit 6 in a state of turning off the analog switch, when at least one of the PMOS transistors M4 and M5 is turned on in the power-supply-potential detection circuit 5.

The potential comparison circuit 6 supplies a potential of the output node BG to the first node IO in a state that the potential of the first node IO is not lower than the total of potential of the second node OI and the threshold potential of the PMOS transistor M6, when the potential of the first node IO is supplied to the circuit 6 from the power-supply-potential detection circuit 5. The potential comparison circuit 6 supplies the potential of the output node BG to the second node OI in a state that the potential of the second node OI is not lower than the total of the potential of the first node IO and the threshold potential of the PMOS transistor M7, when the potential of the second node OI is supplied to the circuit 6 from the power-supply-potential detection circuit 5.

Thus, when at least one of the first node IO and the second node OI has higher potential than the power supply, the potential comparison circuit 6 compares the potential of the first node IO with the potential of the second node OI and selects the higher potential to supply to the output node BG in a state of turning off the analog switch 2. In such a manner, the higher potential is supplied to the substrate potential of the PMOS transistor M1.

The output node BG of the potential comparison circuit 6 is connected to the substrate of the PMOS transistor M1, the cathode of the diode D0 in the inverter 4, and the source of the PMOS transistor M2. When the analog switch 2 is turned off, the PMOS transistor M2 in the inverter 4 has been turned on. The potential of the output node BG of the potential comparison circuit 6 is unchanged to be supplied to the output node n3 of the inverter 4 and the gate of the PMOS transistor M1. In a state that the analog switch 2 is turned off, when the output node BG of the potential comparison circuit 6 is connected to the first node IO or the second node OI and either one of the first node IO and the second node OI has higher potential, the higher potential is supplied to the gate of the PMOS transistor M1, As described above, the higher potential is supplied to the substrate and the gate potentials of the PMOS transistor M1 so that the PMOS transistor M1 is reliably turned off.

FIG. 2 is a circuit diagram of a semiconductor integrated circuit 1 according to a comparative example. The semiconductor integrated circuit 1 of FIG. 2 eliminates the power-supply-potential detection circuit 5 and the potential comparison circuit 6 from the circuit in FIG. 1. The analog switch 2 includes the PMOS transistor MO and the PMOS transistor M1 in the semiconductor integrated circuit 1 in FIG. 2. In a state that the analog switch 2 is turned off, when the potential of the first node IO is higher than the potential VCC of the power supply, a current passes through a parasitic diode D1, a substrate BG, and a source-to-drain path of the PMOS transistor M2 in the inverter 4 to flow to the gate of the PMOS transistor M1, as shown by the dotted line. The parasitic diode D1 is formed between the source and drain of the PMOS transistor M1. A voltage drop of a forward voltage arises from the current passing through the parasitic diode D1. Thus, the gate potential is slightly lower than the source potential at the PMOS transistor M1 so that the PMOS transistor M1 is weakly turned on. The PMOS transistor M1 that has been weakly turned on causes a leak current to flow between the two nodes IO and OI of the analog switch 2, although the analog switch 2 should be turned off.

By contrast, in a state that the analog switch 2 is turned off, when at least one of the potentials of the first node IO and the second node OI is higher than the potential VCC of the power supply, the semiconductor integrated circuit 1 in FIG. 1 supplies the higher potential to the substrate and the gate of the PMOS transistor M1. Thus, the semiconductor integrated circuit 1 of FIG. 1 does not weakly turn on the PMOS transistor M1.

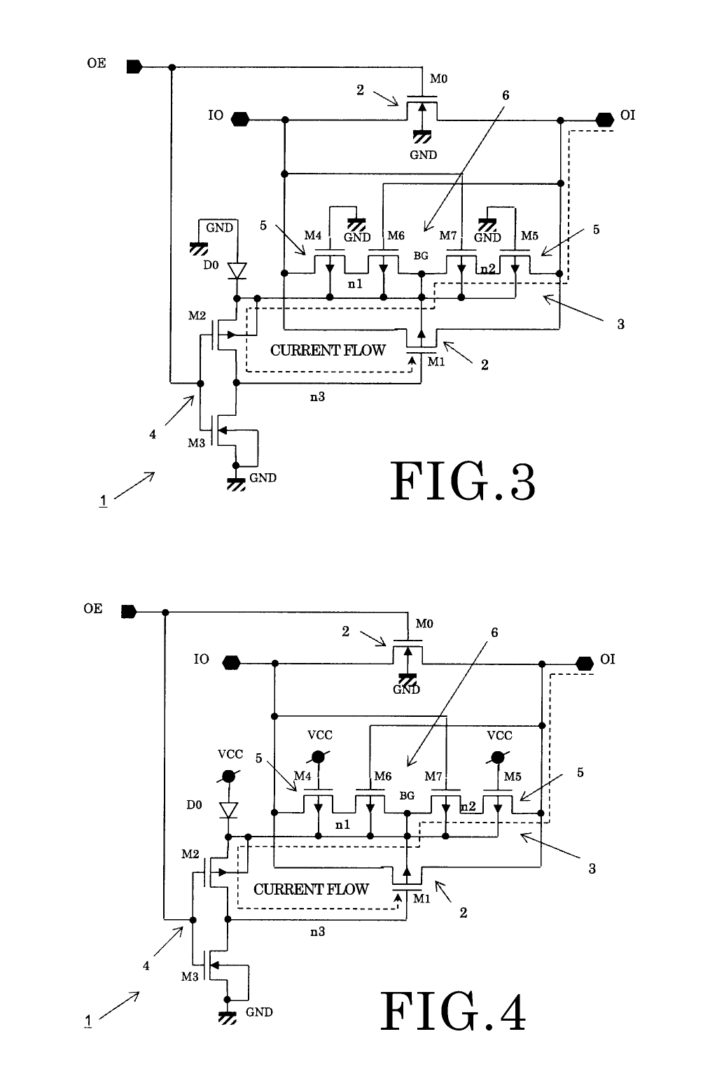

The gates of the PMOS transistors M4 and M5 in the power-supply-potential detection circuit 5 are normally set to the power-supply potential VCC. When the power-supply potential VCC is not supplied to the gates of the PMOS transistors M4 and M5, the gates have a potential of 0 V. FIG. 3 is a circuit diagram corresponding to the state described above. The circuit of FIG. 3 is different from the circuit of FIG. 1 in that the gates of the PMOS transistors M4, M5 and the anode of the diode D0 are not set to the power-supply potential VCC, but set as a potential of 0 V, otherwise the same.

In the power-supply-potential detection circuit 5 in FIG. 3, the PMOS transistor M4 is turned on when the potential of the first node IO is not lower than the threshold potential of the PMOS transistor M4. The PMOS transistor M5 is turned on when the potential of the second node OI is not lower than the threshold potential of the PMOS transistor M5.

Electrical current passes from the second node OI in a state of turning off the analog switch 2, when the potential of the second node OI is higher than the threshold voltage of the PMOS transistor M5 which is higher than the first node IO. The path of the current is denoted by the dotted arrow in FIG. 3.

The source of the PMOS transistor M5 is connected to the second node OI, and the gate of the PMOS transistor M5 is set to a potential of 0 V. As a result, when the potential of the second node OI is not lower than the threshold voltage of the PMOS transistor M5, the PMOS transistor M5 is turned on so that the source of the PMOS transistor M7 has the same potential as the second node OI. The PMOS transistor M7 is turned on and the output node BG in the potential comparison circuit 6 has the same potential as the second node OI in a state that the gate of the PMOS transistor M7 has the same potential as the first node IO, when the second node OI has a potential not lower than the total of the threshold voltage of the PMOS transistor M7 and the potential of the first node IO. The PMOS transistor M2 in the inverter 4 is turned on at this time. As a result, the current passes from the second node OI to the gate of the PMOS transistor M1 through each source-to-drain path of the PMOS transistors M5, M7, and M2. The current causes the gate of the PMOS transistor M1 to have the same potential as the second node OI. As a result described above, the PMOS transistor M1 can be reliably turned off.

Thus, the PMOS transistor M1 is enabled to be reliably turned off in a state that the power-supply potential VCC is not supplied to the semiconductor integrated circuit 1 of FIG. 1, when either one of the potentials of the first node IO and the second node OI is higher than the threshold voltage of the PMOS transistor M6 or M7 which are higher than the other potential.

A current path from the second node OI is shown in FIG. 4, in a state the power-supply potential VCC is supplied to the analog switch 2 to be turned off. In this case, the potential of the second node OI is higher than the threshold voltage of the PMOS transistor M5 which is higher than the potential VCC of the power supply. Further, the potential of the second node OI is higher than the threshold voltage of the PMOS transistor M7 which is the higher than the potential of the first node IO.

In the case described above, the source of the PMOS transistor M5 is set to the potential of the second node OI, and the gate of the PMOS transistor M5 is set to the power-supply potential VCC. As a result, the PMOS transistor M5 is turned on, and the source of the PMOS transistor M7 has the same potential as the second node OI. Since the gate of the PMOS transistor M7 has the same potential as the first node IO, the PMOS transistor M7 is also turned on, and the potential of the output node BG of the potential comparison circuit 6 becomes equal to potential of the second node OI. Thus, a current passes from the second node OI to the gate of the PMOS transistor M1 as shown by the dotted arrow in FIG. 4 in the same way in FIG. 3, so that the gate of the PMOS transistor M1 is supplied the potential of the second node OI.

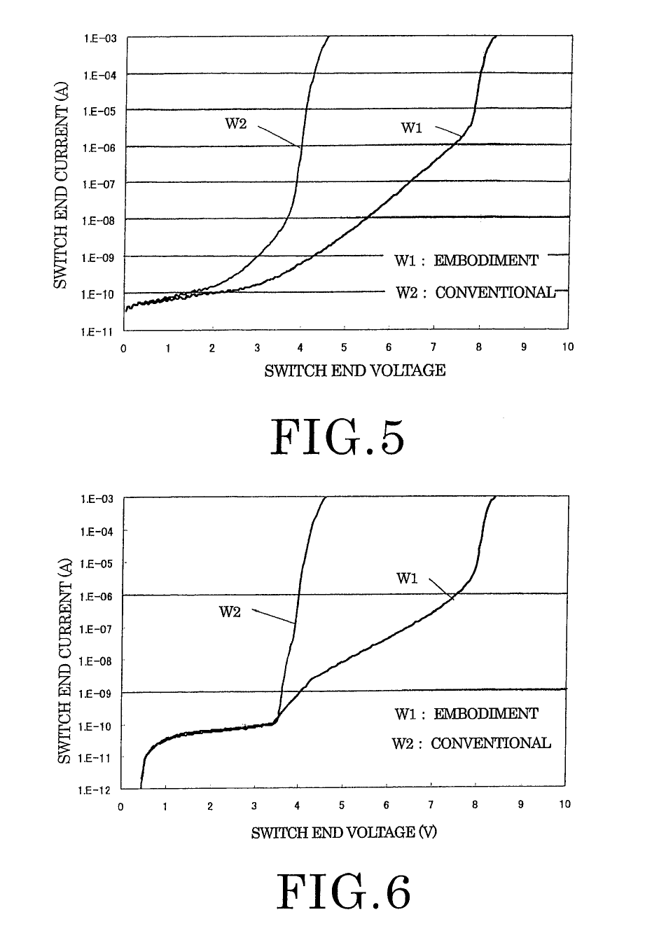

FIG. 5 is a graph showing characteristics of the analog switch 2 being turned off in FIGS. 1 and 2 when the analog switch 2 is supplied the power-supply potential VCC. FIG. 6 is a graph showing characteristics of the analog switch 2 being turned off in FIGS. 1 and 2 when the analog switch 2 is not supplied the power-supply potential VCC. The horizontal axes in the graphs in FIGS. 5 and 6 denote a potential difference between the first node IO and the second node OI. The vertical axes in the graphs in FIGS. 5 and 6 denote an electrical current between the first node IO and the second node OI. The curves w1 in the graphs of FIGS. 5 and 6 denote characteristics of the analog switch 2 in FIG. 1. The curves w2 in the graphs in FIGS. 5 and 6 denote characteristics of the analog switch 2 of FIG. 2.

As is clear from a comparison between the curves w1 and w2, the analog switch 2 of FIG. 1 shows a less leak current between the first node IO and the second node OI than the analog switch 2 in FIG. 2, although the potential difference increases between the first node IO and the second node OI. As described above, the analog switch 2 of FIG. 1 enables the PMOS transistor M1 included in the analog switch 2 to be turned off when the analog switch 2 is turned off. By contrast, the analog switch 2 in FIG. 2 causes the PMOS transistor M1 to be weakly turned on although the analog switch 2 is turned off.

As shown in FIGS. 5 and 6, as the potential difference increases between the first node IO and the second node OI, the leak current increases between the first node IO and the second node OI. The potential difference is larger in the analog switch 2 of FIG. 1 than in the analog switch 2 of FIG. 2 at the same switching current between the first node IO and the second node OI. FIG. 5 and FIG. 6 show that the analog switch 2 of FIG. 1 enables a breakdown voltage applied between the first node IO and the second node OI to be larger than the analog switch 2 of FIG. 2. The embodiment, therefore, enables the analog switch 2 having a high breakdown voltage.

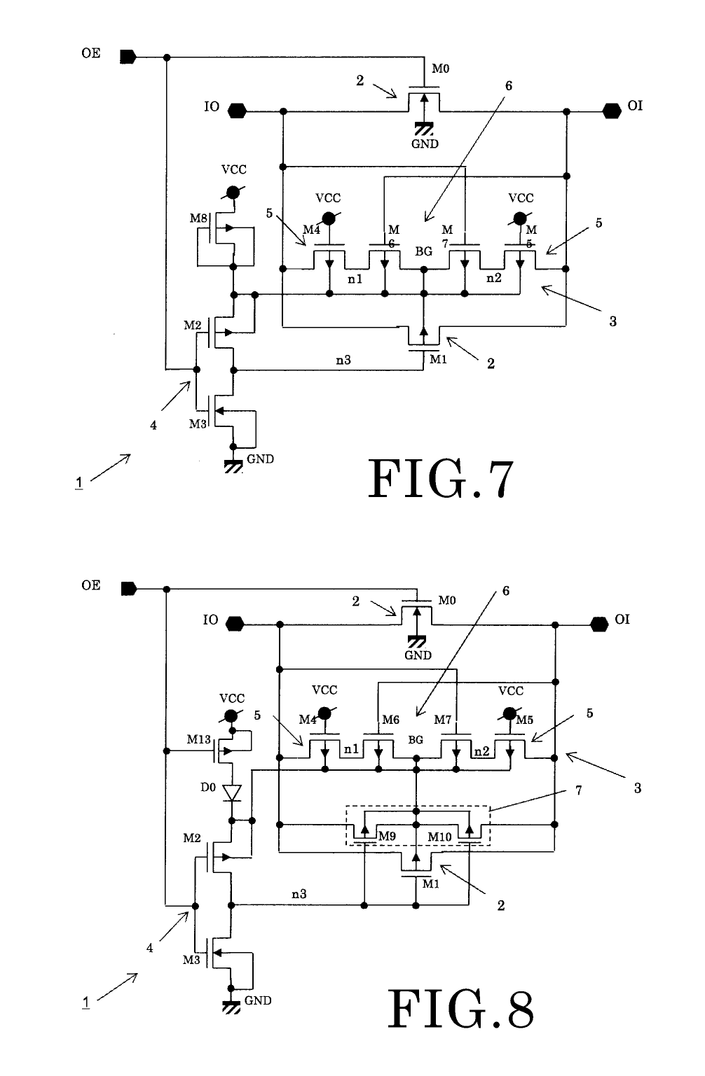

As shown in FIGS. 1, 2, 4, all the transistors are PMOS transistors in the power-supply-potential detection circuit 5 and the potential comparison circuit 6. The diode DO in the inverter 4 can be formed of a PMOS transistor. FIG. 7 is a circuit diagram where the diode D0 in the inverter 4 is formed of a PMOS transistor M8. Connecting the gate and drain of the PMOS transistor M8 makes up the diode D0 having the source of the PMOS transistor M8 as an anode and the gate of the PMOS transistor M8 as a cathode.

In the first embodiment, the substrate and the gate potentials of the PMOS transistor M1 is supplied to the higher potential in a state of turning off the analog switch 2, when at least one of potentials of the first node IO and the second node OI is higher than the potential VCC of the power supply. Therefore, the PMOS transistor M1 can be reliably turned off. As a result, a leak current between the first node IO and the second node OI is prevented despite of a potential difference therebetween in a state of turning off the analog switch 2.

### Second Embodiment

A second embodiment described below adds a function to prevent a substrate bias effect to the analog switch 2 according to the first embodiment.

FIG. 8 is a circuit diagram of the semiconductor integrated circuit 1 in accordance with the second embodiment. The semiconductor integrated circuit 1 in FIG. 8 is configured by adding a substrate bias circuit 7 to the semiconductor integrated circuit 1 in FIG. 1. The substrate bias circuit 7 includes PMOS transistors M9 and M10. The gates of the PMOS transistors M9 and M10 are connected to the output node n3 of the inverter 4 as well as the gate of the PMOS transistor M1. The source of the PMOS transistor M9 is connected to the first node IO, and the drain of the PMOS transistor M9 is connected to the substrate BG of the PMOS transistor M1. The source of the PMOS transistor M10 is connected to the second node OI, and the drain of the PMOS transistor M10 is connected to the substrate BG of the PMOS transistor M1.

The embodiment includes the substrate bias circuit 7 to prevent an unintentional change of the substrate potential.

The substrate bias circuit 7 operates when the analog switch 2 is turned on. In a case described above, the switch control signal OE is high, the NMOS transistor M3 is turned on, and the output node n3 has potential equal to the ground potential GND. As a result, the gates of the PMOS transistor M1, M9, and M10 acquire the ground potential GND to turn on the transistors M1, M9, and M10. The first node IO is connected to the source of the PMOS transistor M9, and the second node OI is connected to the source of the PMOS transistor M10. As a result, the substrate of the PMOS transistor M1 is set to a potential of the first node IO or a potential of the second node OI, whichever is higher.

The inverter 4 in FIG. 8 differs from the inverter 4 of the first embodiment in a circuit configuration. Specifically, the inverter 4 does not connect the anode of the diode D0 to the power-supply with the potential VCC, but connects the PMOS transistor M13 to a line between the anode of the diode D0 and the power supply with the potential VCC. The source of the PMOS transistor M13 is supplied the power-supply potential VCC, the drain of the PMOS transistor M13 is connected to the anode of the diode D0, and the gate of the PMOS transistor M13 is inputted the switch control signal OE.

Adding the PMOS transistor M13 to the inverter 4 of FIG. 8 is to prevent short-circuit current flowing from the power supply to the first and second nodes IO and OI.

It is assumed that the inverter 4 does not include the PMOS transistor, a current passes from the power supply with the potential VCC through an anode-to-cathode path of the diode D0 and source-to-drain paths of the PMOS transistors M9, M10 both having been turned on, and then flows into the first and second nodes IO, OI when the analog switch 2 is turned on.

By contrast, the PMOS transistor M13 including the inverter 4 as shown in FIG. 8 is turned off in accordance with the high switch control signal OE when the analog switch 2 is turned on. At this time, the current is unlikely to pass through the anode-to-cathode path of the diode D0 and the source-to-drain paths of the PMOS transistors M9, M10 from the power supply with the potential VCC, thereby preventing the short-circuit current flowing from the power supply into the first and second nodes IO, OI.

The substrate bias circuit 7 enables the substrate of the PMOS transistor M1 to have potential of the first node IO or potential of the second node OI, whichever is higher. The substrate bias circuit 7 prevents changes in the substrate potential of the PMOS transistor M1, thereby preventing the change in the threshold voltage of the PMOS transistor M1.

### Third Embodiment

A third embodiment described below speeds up turning on the PMOS transistors M4 and M5 included in the power-supply-potential detection circuit 5 within the analog switch 2 according to the first embodiment.

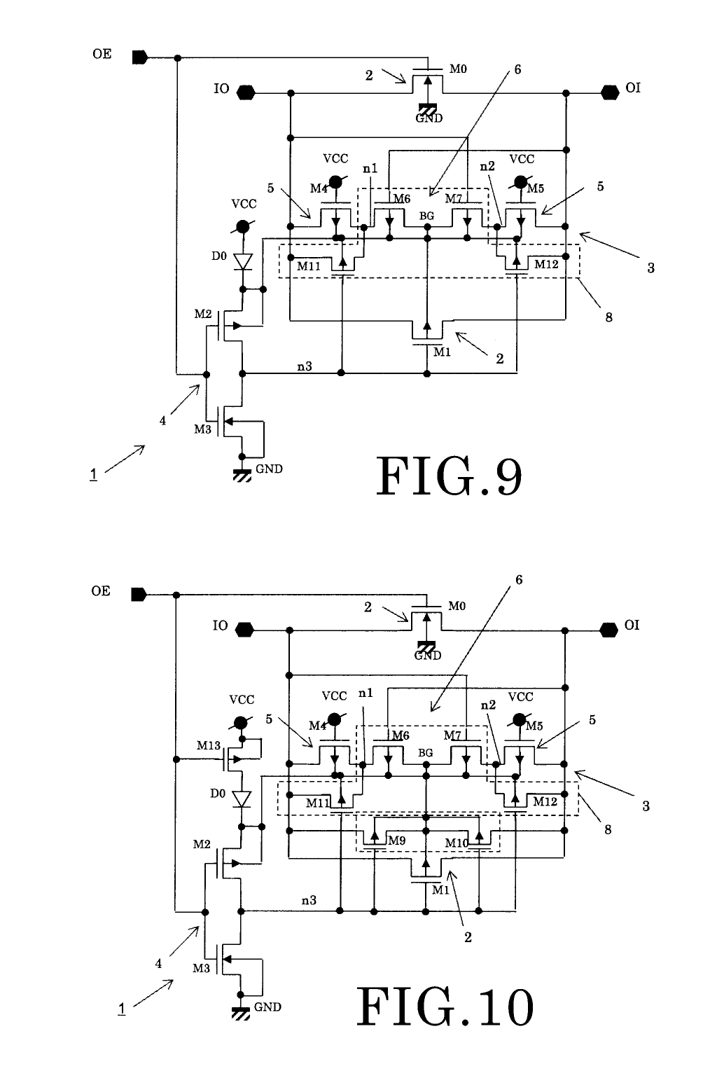

FIG. 9 is a circuit diagram of a semiconductor integrated circuit 1 according to the third embodiment. The semiconductor integrated circuit 1 in FIG. 9 is configured by adding a potential-speed-up circuit to the semiconductor integrated circuit 1 in FIG. 1. The potential-speed-up circuit 8 inputs a potential of the first node JO and a potential of the second node OI to the potential comparison circuit 6 when the PMOS transistor M1 is turned off, before the power-supply-potential detection circuit 5 outputs an effective signal.

The potential-speed-up circuit 8 includes PMOS transistors M11 and M12. The gates of the PMOS transistors M11 and M12 are connected to the output node n3 of the inverter 4 in the same way as the gate of the PMOS transistor M1. The source of the PMOS transistor M11 is connected to the first node IO, and the drain of the PMOS transistor M11 is connected to the drain of the PMOS transistor M4. The source of the PMOS transistor M12 is connected to the second node OI, and the drain of the PMOS transistor M12 is connected to the drain of the PMOS transistor M5.

The potential-speed-up circuit 8 supplies the potential of the first node IO to the drain of the POMS transistor M4 before the POMS transistor M4 is turned on, and supplies the potential of the second node OI to the drain potential of the PMOS transistor M5 before the PMOS transistor M5 is turned on.

The potential-speed-up circuit 8 operates when the analog switch 2 is turned off. At this time, the switch control signal OE becomes low to turn on the PMOS transistor M2 in the inverter 4, and the output node n3 of the inverter 4 acquires a potential equal to a potential of VCC−Vf. Vf is forward potential of the diode D0. As a result, the gates of the PMOS transistors M1, M11, and M12 are also supplied the potential VCC−Vf.

Thus, when the analog switch 2 is turned off, the gate potential VCC−Vf of the PMOS transistors M11 and M12 becomes lower than the gate potential VCC of the PMOS transistor M4 and of M5. As a result, the PMOS transistors M11 and M12 are turned on when the first and second nodes IO and OI have lower potential. That is, the PMOS transistors M11 and M12 are turned on before the PMOS transistors M4 and M5 are turned on.

When the PMOS transistors M11 and M12 are turned on, the source of the PMOS transistor M6, which is an input node of the potential comparison circuit 6, has the same potential as the first node IO, and the source of the PMOS transistor M7 has the same potential as the second node OI. This state turns on the PMOS transistor M6 to cause the output node BG of the potential comparison circuit 6 to have the same potential as the first node IO when the potential of the first node IO has potential not lower than the total of potential of the second node OI and the threshold voltage of the PMOS transistor M6. When the second node OI has potential not lower than the total of potential of the first node IO and the threshold voltage of the PMOS transistor M7, the PMOS transistor M7 is turned on to cause the output node BG of the potential comparison circuit 6 to have the same potential as the second node OI, thereby turning on the PMOS transistor M5 to stabilize potential of the output node BG.

Thus, the potential-speed-up circuit 8 compares potential of the first node IO with the potential of the second node OI to output the higher potential to the output node BG before the potential of the first node IO exceeds the power-supply potential VCC or before the potential of the second node IO exceeds the potential VCC. The potential-speed-up circuit 8 speeds up comparison processing in the potential comparison circuit 6.

Alternatively, the substrate bias circuit 7 in FIG. 8 can be added to the semiconductor integrated circuit 1 in FIG. 9. FIG. 10 is a circuit diagram of a semiconductor integrated circuit 1 that further includes the substrate bias circuit in FIG. 8 and the potential-speed-up circuit in FIG. 9. The semiconductor integrated circuit 1 in FIG. 10 is configured by adding the substrate bias circuit 7 in FIG. 8 and the potential-speed-up circuit 8 in FIG. 9 to the semiconductor integrated circuit 1 in FIG. 1. The inverter 4 in the semiconductor integrated circuit 1 in FIG. 10 has the same configuration as the inverter 4 in FIG. 8. The inverter 4 prevents short-circuit current from flowing into the first and second nodes IO and OI by turning off the PMOS transistor M13 when the analog switch 2 is turned on.

The semiconductor integrated circuit 1 in FIG. 10 enables it to prevent the substrate bias effect of the PMOS transistor M1 included in the analog switch 2 and speed up the comparison processing in the potential comparison circuit 6 by early supplying a potential to the input node of the potential comparison circuit 6.

### Fourth Embodiment

The switch control circuits 3 of the first to third embodiments described above include PMOS transistors as transistors, whereas the analog switch 2 and the inverter 4 include PMOS and NMOS transistors. A semiconductor integrated circuit 1 according to a fourth embodiment described below includes just PMOS transistors as transistors.

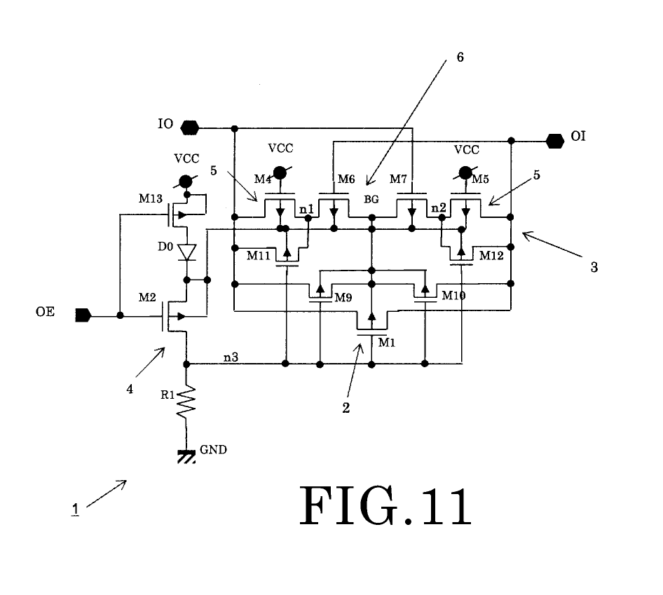

FIG. 11 is a circuit diagram of the semiconductor integrated circuit 1 according to the fourth embodiment. The semiconductor integrated circuit 1 in FIG. 11 includes the analog switch 2, the inverter 4, and the switch control circuit 3 in the same way as the semiconductor integrated circuit 1 in FIG. 10.

An internal configuration of the analog switch 2 and the inverter 4 in FIG. 11 is different from that in FIG. 10. The internal configuration of the switch control circuit 3 in FIG. 11 is the same as that of the switch control circuit 3 in FIG. 10.

The analog switch 2 in FIG. 11 includes just the PMOS transistor M1 connected to a line between the first node IO and the second node OI, and lacks the NMOS transistor M0 in FIG. 10.

The inverter 4 in FIG. 11 includes the PMOS transistor M13, the PMOS transistor M2, and a resistive element (impedance element) R1, all of which are electrically vertically laminated between the power-supply potential VCC and the ground potential GND. The resistive element R1 is provided as a substitute for the NMOS transistor M3 in FIG. 10.

The output node n3 of the inverter 4 is connected to a line between the drain of the PMOS transistor M2 and the resistive element R1. The respective gates of the PMOS transistor M1, M9, and M10 are connected in parallel to the output node in the same way as in FIG. 10.

When the switch control signal OE becomes low, turning on the PMOS transistor M2 in the inverter 4 causes the output node n3 of the inverter 4 to have balance that subtracts forward potential of the diode D0 from the power-supply potential VCC. When the switch control signal OE becomes high, turning off the PMOS transistor M2 in the inverter 4 causes the output node n3 of the inverter 4 to have potential equal to the ground potential GND.

Thus, when the inverter 4 lacks the NMOS transistor M3, connecting the resistive element R1 to a line between the drain of the PMOS transistor M3 and the ground with potential GND enables it to supply the ground potential GND to the output node of the PMOS transistor M2 that is turned off.

When the analog switch 2 includes just the PMOS transistor M1, turning on or off the PMOS transistor M1 enables it to electrically connect or disconnect the first IO and the second node OI by turning on and off the PMOS transistors M1.

The semiconductor integrated circuit 1 in FIG. 11 has shown an example that the semiconductor integrated circuit 1 in FIG. 10 includes just the PMOS transistors as transistors therein. Alternatively, the semiconductor integrated circuits 1 in FIGS. 1, 7, 8, and 9 can include the PMOS transistors as transistors therein in the same way as that in FIG. 11.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor integrated circuit, comprising:
a first transistor configured to switch whether or not a first node electrically connects to a second node; and
a switch control circuit configured to supply higher potential to a substrate potential of the first transistor in a state of turning off the first transistor, when at least one of potentials of the first node and the second node is equal to or higher than a predetermined potential which is higher than a potential of a power supply.

2. The semiconductor integrated circuit according to claim 1, further comprising:
an inverter configured to invert a switch control signal inputted from an outside to an inverted signal,
wherein the switch control circuit is configured to supply higher potential to the inverter, when at least one of the potentials of the first node and the second node is equal to or higher than the predetermined potential which is higher than the potential of the power supply and
the inverter supplies a potential supplied from the switch control circuit to the gate of the first transistor.

3. The semiconductor integrated circuit according to claim 1, wherein
the switch control circuit includes a power-supply-potential detection circuit and a potential comparison circuit,
the power-supply-potential detection circuit configured to determine whether or not at least one of the potentials of the first node and the second node is higher potential than the power supply,
the potential comparison circuit configured to select and to output the higher potential, when the power-supply-potential detection circuit determines that at least one of the potentials of the first node and the second node is the higher than the power supply, and
the inverter configured to supply a potential from the potential comparison circuit to the gate of the first transistor.

4. The semiconductor integrated circuit according to claim 2, wherein
the switch control circuit includes a substrate bias circuit configured to set the potential of the first node and the second node, and the substrate potential of the first transistor to a common potential; and
the common potential is supplied to the inverter, when the first node electrically connects to the second node.

5. The semiconductor integrated circuit according to claim 2, wherein
the switch control circuit includes a potential-speed-up circuit, the potential-speed-up circuit is configured to input the potentials of the first node and the second node to the potential comparison circuit before the power-supply-potential detection circuit outputs a determination result.

6. The semiconductor integrated circuit according to claim 2, wherein
the first transistor is a P-channel MOS transistor and each of the all transistors included in the switch control circuit is a P-channel transistor.

7. The semiconductor integrated circuit according to claim 2, further comprising:
a second transistor of an N-type channel MOS transistor configured to switch whether or not the first node electrically connects the second node based on the switch control signal.

8. The semiconductor integrated circuit according to claim 7, wherein
the first transistor and the second transistor configured to be turned on or off in synchronization.

9. The semiconductor integrated circuit according to claim 7, wherein
the substrate potential of the first transistor is supplied to an output node of the switch control circuit and the substrate potential of the second transistor is supplied to ground potential.

10. The semiconductor integrated circuit according to claim 2, wherein
the inverter includes a diode, a third transistor of a P-channel MOS transistor and a fourth transistor of a N-channel MOS transistor,
the diode has an anode connected to ground and a cathode connected to the output node of the switch control circuit,
the third transistor has a source connected to ground, a drain connected to the output node of the inverter, and a gate into which the switch control signal is inputted, and
the fourth transistor has a source connected to ground, a drain connected to the output node of the inverter, and a gate into which the switch control signal is inputted.

11. The semiconductor integrated circuit according to claim 2, wherein
the inverter includes the diode, the third transistor of a P-channel MOS transistor and an impedance element,
the diode has the anode connected to ground and the cathode connected to the output node of the switch control circuit,
the third transistor has the source connected to ground, the drain connected to the output node of the inverter, and the gate into which the switch control signal is inputted, and
the impedance element is connected to a line between an output node of the inverter and ground.

12. The semiconductor integrated circuit according to claim 3, wherein
the power-supply-potential detection circuit includes fifth and sixth transistors,
the fifth transistor has a source connected to the potential comparison circuit through the first node and a drain connected to the potential comparison circuit through a third node, and
the sixth transistor has a source connected to the potential comparison circuit through the second node and a drain connected to the potential comparison circuit through a fourth node.

13. The semiconductor integrated circuit according to claim 12, wherein
the power-supply-potential detection circuit outputs the potential of the first node from the third node when the potential of the first node is higher than the power-supply potential, and outputs the potential of the first node from the fourth node when the potential of the second node is higher than the power-supply potential.

14. The semiconductor integrated circuit according to claim 3, wherein
the potential comparison circuit includes seventh and an eighth transistors,
the seventh transistor has a source connected to the drain of the fifth transistor and a seventh connected to an output node of the potential comparison circuit, and
the eighth transistor has a source connected to the drain of the sixth transistor and a drain connected to the output node of the potential comparison circuit.

15. The semiconductor integrated circuit according to claim 14, wherein
a potential of the drain of the seventh transistor is configured to supply to the potential of the first node when the fifth transistor is turned on, and a potential of the drain of the eighth transistor is configured to supply to the potential of the second node when the sixth transistor is turned on.

16. The semiconductor integrated circuit according to claim 4, wherein
the substrate bias circuit includes ninth transistor and tenth transistors,
each gate of the ninth and tenth transistors is connected to the output node of the inverter, a source and a drain of the ninth transistor are connected to the first node and to the substrate of the first transistor, respectively, a source and a drain of the tenth transistor are connected to the second node and the substrate of the first transistor, respectively.

17. The semiconductor integrated circuit according to claim 4, wherein
the inverter includes an eleventh transistor between the anode of the diode and the power supply,
a source and a drain of the eleventh transistor are connected to the power supply and the anode of the diode, respectively, and the switch control signal is inputted into an eleventh gate of the eleventh transistor.

18. The semiconductor integrated circuit according to claim 5, wherein
the potential-speed-up circuit includes twelfth transistor and thirteenth transistors,
each gate of the twelfth and thirteenth transistors is connected to the output node of the inverter, a source and a drain of the twelfth transistor are connected to the first node and the drain of the fifth transistor, respectively, a source and a drain of the thirteenth transistor are connected to the second node and the drain of the sixth transistor.

19. The semiconductor integrated circuit according to claim 18, further comprising:
a substrate bias circuit configured to supply the common potential to the substrate potential of the first transistor, and the potentials of the first node and the second node, and the common potential is supplied to the inverter.

20. The semiconductor integrated circuit according to claim 18, wherein
the inverter includes the eleventh transistor between the anode of the diode and the potential of the power supply, the source and the drain of the eleventh transistor are connected to the power supply and the anode of the diode, respectively, and the switch control signal is inputted into the gate of the eleventh transistor.
